(19) United States
(12) Patent Application Publication
(10) Pub. No.: US 2026/0057197 A1
(43) Pub. Date: Feb. 26, 2026

(54) ELECTRONIC CIRCUIT AND DEVICE FOR COMPUTATION

(71) Applicant: 14873891 Canada Inc. dba Aspirare, Ottawa (CA)

(72) Inventors: Joshua CHAN, Ottawa (CA); Girish BABU, Burlington (CA)

(21) Appl. No.: 18/989,297

(22) Filed: Dec. 20, 2024

Related U.S. Application Data
(60) Provisional application No. 63/685,776, filed on Aug. 22, 2024.

(51) Int. Cl. G06J 1/00; H03M 1/74

(52) U.S. Cl. CPC G06J 1/00; H03M 1/74

(57) ABSTRACT

An electronic circuit is provided. The electronic circuit includes a plurality of digital-to-analog converters (DACs) configured to generate a plurality of analog input signals. The electronic circuit includes a computation matrix coupled to the plurality of DACs and configured to receive the plurality of analog input signals from the plurality of DACs. The computation matrix comprises a plurality of computation nodes. Each computation node comprises: a bias circuit configured to generate a positive bias current and a negative bias current based on an analog input signal among the plurality of analog input signals, and a computation circuit configured to generate a computation result current based on the positive bias current, the negative bias current, and a digital weight signal. An electronic device and a method are also provided.

### BACKGROUND

Electronic circuits, such as semiconductor integrated circuit (IC), have long been used for data processing tasks. Recently, with the development of artificial intelligence (AI) technology, some electronic circuits have been designed for AI applications, which often involve computations based on a large amount of data with high complexity. For example, when used in data centers, AI applications can improve the efficiency and accuracy of data analytics and resource management.

### SUMMARY

In a general aspect, an electronic circuit is provided. The electronic circuit includes a plurality of digital-to-analog converters (DACs) configured to generate a plurality of analog input signals. The electronic circuit includes a computation matrix coupled to the plurality of DACs and configured to receive the plurality of analog input signals from the plurality of DACs. The computation matrix includes a plurality of computation nodes. Each computation node includes: a bias circuit configured to generate a positive bias current and a negative bias current based on an analog input signal among the plurality of analog input signals, and a computation circuit configured to generate a computation result current based on the positive bias current, the negative bias current, and a digital weight signal.

In some implementations, for each computation node, the bias circuit includes a current mirror circuit.

In some implementations, for each computation node, the current mirror circuit includes: an input transistor configured to receive analog input signal; a p-type metal–oxide–semiconductor (PMOS) output transistor configured to generate the positive bias current; and an n-type metal–oxide–semiconductor (NMOS) output transistor configured to generate the negative bias current.

In some implementations, for each computation node, the computation circuit includes a plurality of groups of weighting transistors, an output node, and a control circuit. Each group of weighting transistors includes at least one a PMOS transistor, at least one NMOS output transistor, a first switch configured to couple the at least one PMOS transistor to the output node, and a second switch configured to couple the at least one NMOS transistor to the output node. The control circuit is configured to control the first switch and the second switch based on the digital weight signal.

In some implementations, for each computation node, the computation result current of that computation node is a superposition of i) a current at the output node of that computation node, and ii) a computation result current generated by an adjacent computation node in the computation matrix.

In some implementations, for each computation node, the plurality of groups of weighting transistors correspond to a plurality of multipliers.

In some implementations, each group of weighting transistors has at least one of: a number of PMOS transistors corresponding to a multiplier of that group and a number of NMOS transistors corresponding to the multiplier of that group, a width of the PMOS transistors corresponding to the multiplier of that group and a width of the NMOS transistors corresponding to the multiplier of that group, or a length of the PMOS transistors corresponding to the multiplier of that group and a length of the NMOS transistors corresponding to the multiplier of that group.

In some implementations, for each computation node, the plurality of multipliers are powers of 2.

In some implementations, the computation matrix includes a plurality of rows and a plurality of columns, and the plurality of DACs are respectively coupled to the plurality of rows.

In some implementations, the electronic circuit further includes a plurality of analog-to-digital converters (ADCs) coupled to the plurality of columns and configured to receive a plurality of analog output signals from the computation matrix and convert the plurality of analog output signals to a plurality of digital output signals.

In some implementations, each DAC includes a plurality of groups of converting transistors, an output node, and a control circuit configured to receive an input digital signal. Each group of converting transistors includes at least one PMOS transistor, at least one NMOS output transistor, a first switch configured to couple the at least one PMOS transistor to the output node, and a second switch configured to couple the at least one NMOS transistor to the output node. The control circuit is configured to control the first switch and the second switch based on the input digital signal.

In some implementations, the computation matrix is a first computation matrix, and the electronic circuit further includes: one or more second computation matrices; and a coupling circuit connected between the first computation matrix and the one or more second computation matrices.

In some implementations, the coupling circuit includes a plurality of diodes.

In some implementations, the electronic circuit further includes: at least one demultiplexer configured to receive digital input data; and a plurality of first-in-first-out (FIFO) circuits coupled between the at least one demultiplexer and the plurality of DACs.

In some implementations, the electronic circuit further includes: at least one multiplexer configured to generate digital output data; and a plurality of FIFO circuits coupled between the at least one multiplexer and the plurality of ADCs.

In another general aspect, an electronic device is provided. The electronic device has a receiver port configured to receive digital input data, a transmitter port configured to transmit digital output data, and a computation circuit configured to receive the digital input data from the receiver port and provide the digital output data to the transmitter. The computation circuit can be implemented similar to the electronic circuit described above.

In another general aspect, a method is provided. The method includes receiving, by a computation matrix and from a plurality of DACs, a plurality of analog input signals. The computation matrix includes a plurality of computation nodes. The method includes, at each computation node, generating a positive bias current and a negative bias current based on an analog input signal among the plurality of analog input signals. The method includes, at each computation node, generating a computation result current based on the positive bias current, the negative bias current, and a digital weight signal.

### BRIEF DESCRIPTION OF THE DRAWINGS

FIG. 1 illustrates an example system where AI accelerators are used in AI applications, according to some implementations.

FIG. 2 illustrates an example electronic device having an AI accelerator, according to some implementations.

FIG. 3A illustrates an example electronic circuit of an AI accelerator, according to some implementations.

FIG. 3B illustrates a plurality of example computation nodes in the electronic circuit of FIG. 3A, according to some implementations.

FIG. 4 illustrates a block diagram of a plurality of computation nodes, according to some implementations.

FIG. 5 illustrates an example current mirror circuit, according to some implementations.

FIG. 6 illustrates an example multiplication circuit, according to some implementations.

FIG. 7 illustrates an example DAC circuit, according to some implementations.

FIG. 8 illustrates an example electronic circuit with a plurality of computation matrices, according to some implementations.

FIG. 9 illustrates a flowchart of an example method, according to some implementations.

Figures are not drawn to scale. Like reference numbers refer to like components.

### DETAILED DESCRIPTION

The performance of an AI application can be affected by the application’s capacity to process a large amount of data and make complex computations. For example, in machine learning applications where neural networks are configured to learn from training data and make inferences (e.g., predictions), the ability for a neural network to process a large amount of training data and the depth (e.g., number of layers) of the neural network can affect the accuracy of its predictions. To accommodate the increasing needs for AI applications with high computation capacity, AI accelerator circuits are provided with architectures designed for conducting complex computations. In a typical AI accelerator architecture, computation is performed in multiplication-accumulation (MAC) circuitry.

Some AI accelerator architectures have MAC circuitry that performs computation in the digital domain. In these architectures, the data is represented as digital code, such as binary bits at different voltage levels, and the multiplication and accumulation operations are performed using digital multipliers and adders made of logic gates. A disadvantage with these architectures is the large number of transistors that constitute the logic gates, which consume large circuit area. Another disadvantage with these architectures is the high power consumption often associated with the operations of the logic gates, e.g., during the transition between logic levels. These disadvantages can limit the potential for these architectures to accommodate the complex and high volume data in AI applications.

Implementations of this disclosure advantageously improve the power consumption and the circuit size of AI accelerators. As described in detail below, the MAC circuitry according to some implementations operates in the analog domain based on current scaling and superposition, which, compared with the digital domain computation, significantly reduces the power consumption and circuit area due to the large number of logic gates. With one or more features of the described circuits, implementations of this disclosure improve the computing capacity of AI accelerators and hence allow for more efficient and more accurate AI applications.

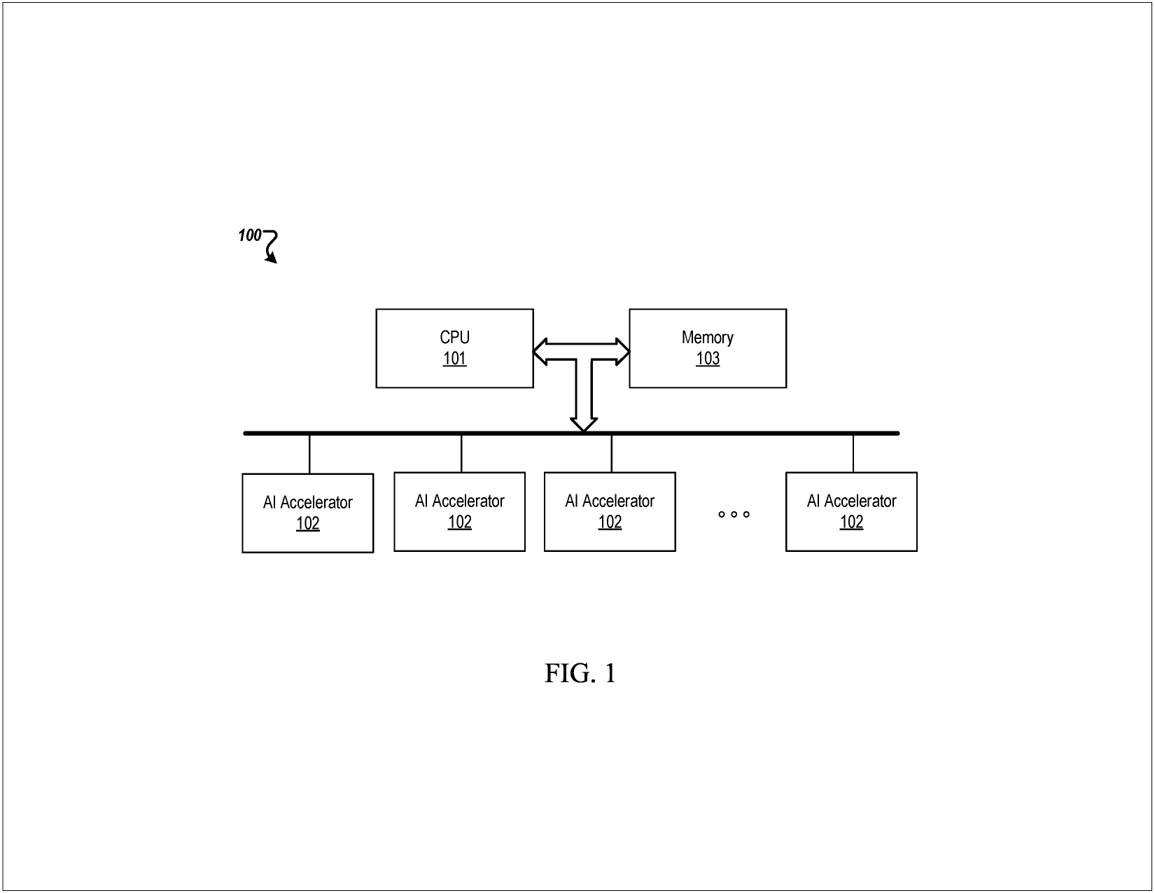

FIG. 1 illustrates an example system 100 where AI accelerators are used to perform AI applications, according to some implementations. System 100 can be implemented, e.g., to manage various aspects of data center operations, such as network resource allocation, power consumption optimization, and data security monitoring.

As illustrated, system 100 includes one or more central processing units (CPUs) 101, one or more memories 103, and one or more AI accelerators 102, which are communicatively coupled to each other. When performing an AI application, CPU 101 can configure AI accelerators 102 to execute computation tasks according to the application. Accordingly, AI accelerators 102 can access data from memory 103 and perform computations, such as MAC operations, based on the data, and output results to memory 103 and/or CPU 101.

Each of AI accelerators 102 can be implemented on a standalone electronic device, such as a circuit board with one or more semiconductor IC chips. Alternatively, multiple AI accelerators 102 can be implemented on a single electronic device or as a single IC chip. Accelerators 102 can be located within the same facility (e.g., server room of a data center) as CPU 101 and memory 103, or can be remotely connected to CPU 101 and memory 103 via network connections.

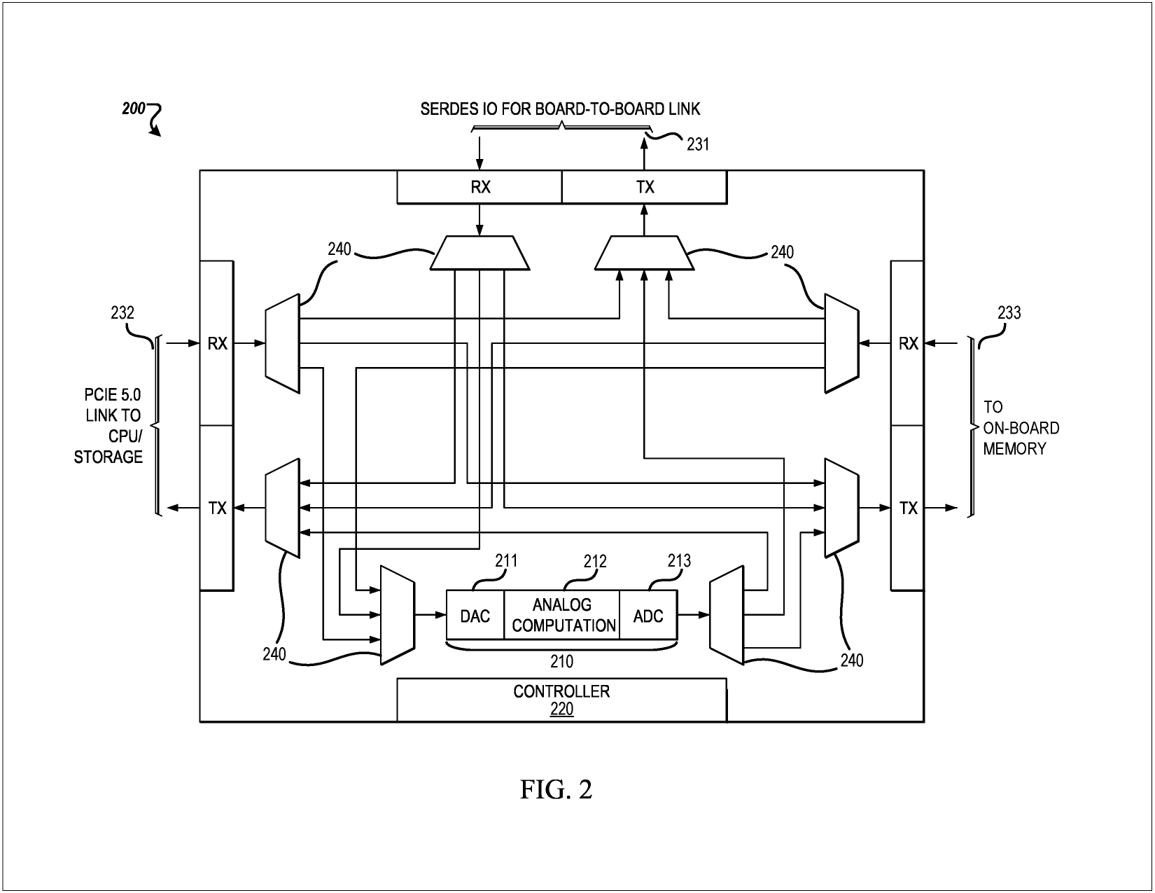

FIG. 2 illustrates an example electronic device 200 having an AI accelerator circuit 210, according to some implementations. Electronic device 200 can be similar to each of AI accelerators 102 in system 100 of FIG. 1 to perform computation tasks of AI applications. Electronic device 200 can be physically implemented on a circuit board whereas circuit 210 can be physically implemented as a semiconductor IC chip.

Electronic device 200 includes one or more receiver (RX) ports and transmitter (TX) ports for exchanging data and control signals with other devices. For example, as illustrated, electronic device 200 includes three pairs of RX and TX ports 231-233. Ports 231 can serve as serializer/deserializer (SerDes) input/output (IO) ports for communications over board-to-board links, such as the communication links between instances of AI accelerators 102 in system 100. Ports 232 can be configured to exchange data with a CPU and/or storage circuits, such as CPU 101 and memory 103 of system 100 of FIG. 1. The communications between ports 232 and the CPU and/or storage circuits can be, e.g., via a peripheral component interconnect express (PCIe) 5.0 link. Ports 233 can be configured to exchange data with an on-board memory, such as a graphics double data rate (GDDR) memory integrated on the same circuit board as electronic device 200. Each pair of ports 231-233 can have corresponding peripheral circuitry 240, which can include one or more circuit components such as buffers, encoders, decoders, filters, equalizers, amplifiers, scramblers, descramblers, etc.

Electronic device 200 also includes AI accelerator circuit 210 and controller 220. While controller 220 is illustrated in FIG. 2 as separate from AI accelerator circuit 210, in some implementations controller 220 can be partially or completely integrated within AI accelerator circuit 210. AI accelerator circuit 210 can be configured to receive digital input data from any RX ports of ports 231-233, perform MAC computations under the control of controller 220, and provide digital output data to any TX ports of ports 231-233. Different from AI accelerator architectures in the digital domain, AI accelerator circuit 210 performs computations in the analog domain. To this end, AI accelerator circuit 210 has analog MAC computing circuit 212, with its input coupled to DAC 211 and output coupled to ADC 213. DAC 211 is configured to convert the received digital input data to analog signals for computation, whereas ADC 231 is configured to convert the analog computation results provided by MAC computing circuit 212 to output digital signals.

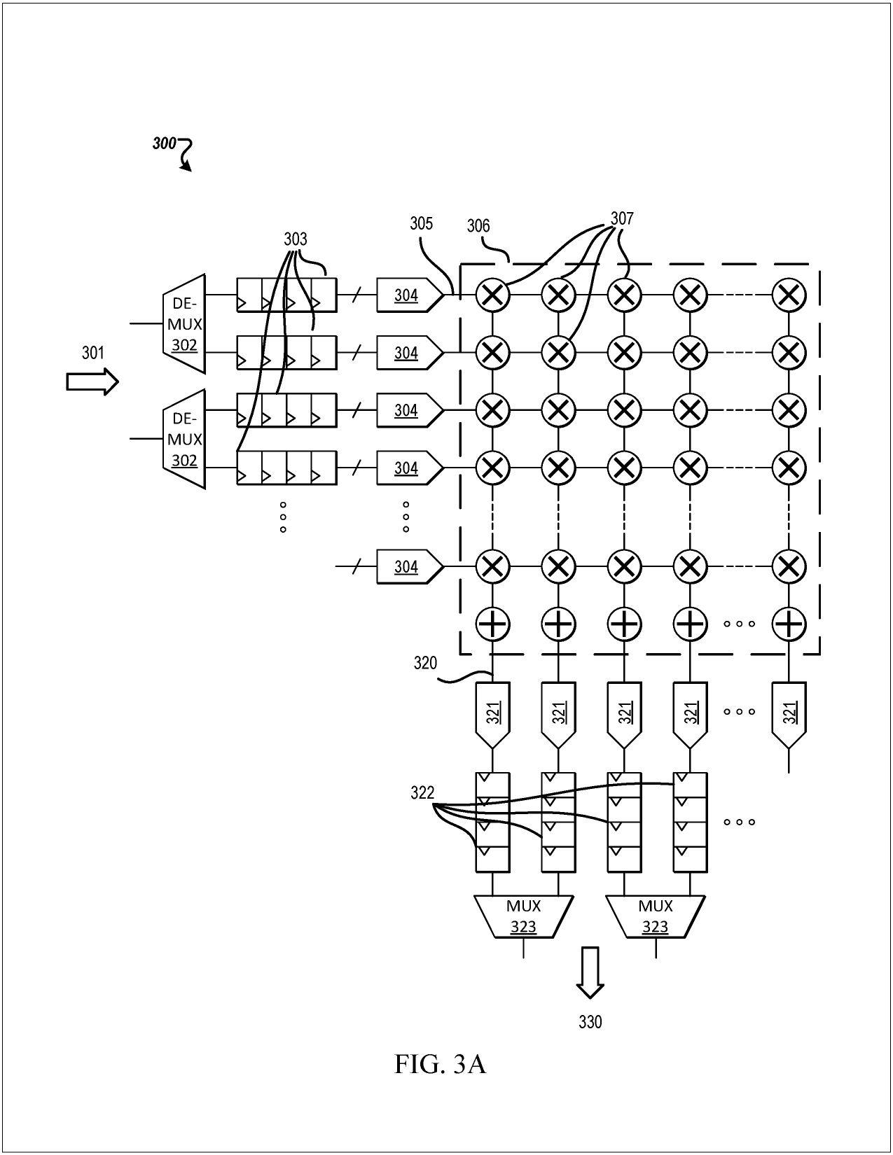

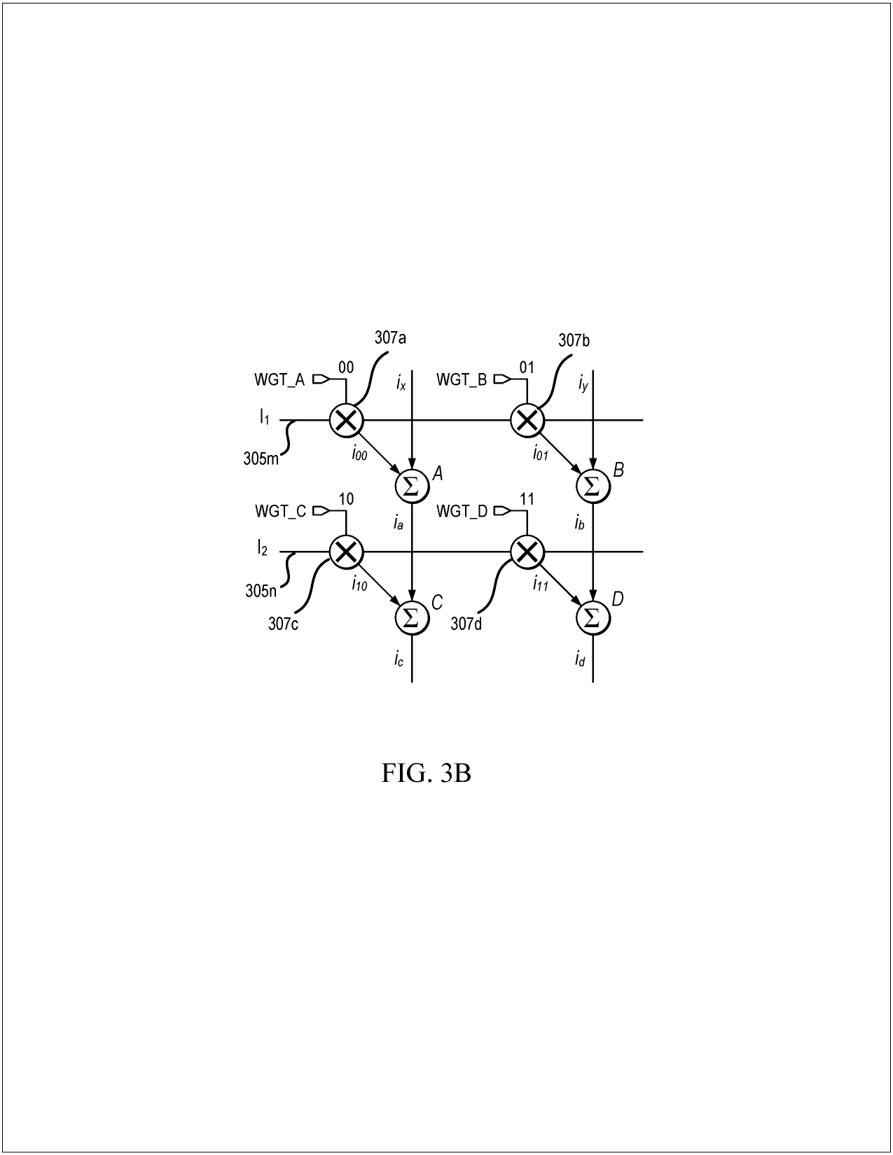

FIG. 3A illustrates an example electronic circuit 300 of an AI accelerator, according to some implementations. Electronic circuit 300 can be similar to AI accelerator circuit 210 of FIG. 2.

Electronic circuit 300 receives digital input data 301, performs computation in the analog domain, and outputs digital output data 330. The computation (e.g., MAC computation) takes place primarily in computation matrix 306, which has a plurality of rows and columns intersecting at a plurality of computation nodes 307, illustrated by the symbol ⨂. The rows of computation matrix 306 are respectively coupled to a plurality of DACs 304, which are configured to convert digital input data 301 to analog input signals 305 respectively input to the rows of computation matrix 306. In some implementations, digital input data 301 undergoes de-multiplexing by one or more de-multiplexers (de-MUXes) 302 before being input to DACs 304. For example, de-MUXes 302 can convert a stream of digital input data 301 into a plurality of streams of parallel data and stores the parallel data in a plurality of FIFO circuits 303. The output of each of FIFO circuits 303 is then input to a respective DAC 304 for converting to an analog input signal 305 in a corresponding row.

Each computation node 307 is configured to perform a multiplication operation. The multiplication takes the current amplitude of analog input signal 305 in the corresponding row as a multiplicand, and takes a digital weight signal at a corresponding column as a multiplier. The multiplication results are output by computation nodes 307 as analog currents, with the current amplitudes representing the value of the multiplication results.

The multiplication results in each column are then added in accumulation operations. The accumulation operations are implemented by superposition of currents output by computation node 307 in the same column. Accordingly, at the output of computation matrix 306 (illustrated as the bottom of the matrix), the current output by each column is a superposition of currents output by all of computation nodes 307 of that column, which is illustrated by the symbol ⨁. The output currents at all columns constitute analog output signals 320.

At the output, the columns of computation matrix 306 are respectively coupled to a plurality of ADCs 321, which are configured to respectively convert analog output signals 320 to digital output signals 330. In some implementations, digital outputs from ADCs 321 are respectively buffered in a plurality of FIFO circuits 322 and undergo multiplexing by one or more multiplexers (MUXes) 302 to become digital output signals 330.

FIG. 3B illustrates a plurality of example computation nodes 307a-307d in electronic circuit 300 of FIG. 3A, according to some implementations. The illustrated computation nodes 307a-307d can be, e.g., a 2-by-2 subset of computation matrix 306. Analog input signal 305m in the upper row is represented by current I₁ and analog input signal 305n in the lower row is represented by current I₂. Both analog input signal 305m and analog input signal 305n can be instances of analog input signals 305 illustrated in FIG. 3A.

Using computation node 307a as an example, computation node 307a is configured to perform multiplication using current I₁ as a multiplicand and using digital weight signal WGT_A as a multiplier. As described above, current I₁ can correspond to an instance of analog input signal 305, which is output by an instance of DAC 304 based on digital input data 301 provided by an AI application. Additionally, digital weight signal WGT_A can also be provided by the AI application. For example, in the training phase of an AI application, digital weight signal WGT_A can be a parameter that affects the influence of a corresponding neuron (e.g., a node of the neural network) in the overall learning process. Digital weight signal WGT_A is represented in the form of one or more binary bits. For example, as illustrated, an AI application can specify that WGT_A is a two-bit signal that equals 2’b00. With the inputs provided by the AI application, computation node 307a is configured to obtain the product of a) digital input data corresponding to analog input signal 305m, which equals the amplitude of current I₁, and b) digital weight signal WGT_A, which equals 2’b00. Similarly, for computation nodes 307b-307d, the AI application can specify that WGT_B, WGT_C, and WGT_D are two-bit signals that equal 2’b01, 2’b10, and 2’b11, respectively. With these inputs, computation nodes 307b-307d are likewise configured to perform multiplications similar to that performed by computation node 307a. It is noted that the two-bit digital weight signals WGT_A to WGT_D are merely provided as examples. Other implementations can have digital weight signals with different number of bits and/or different logic values.

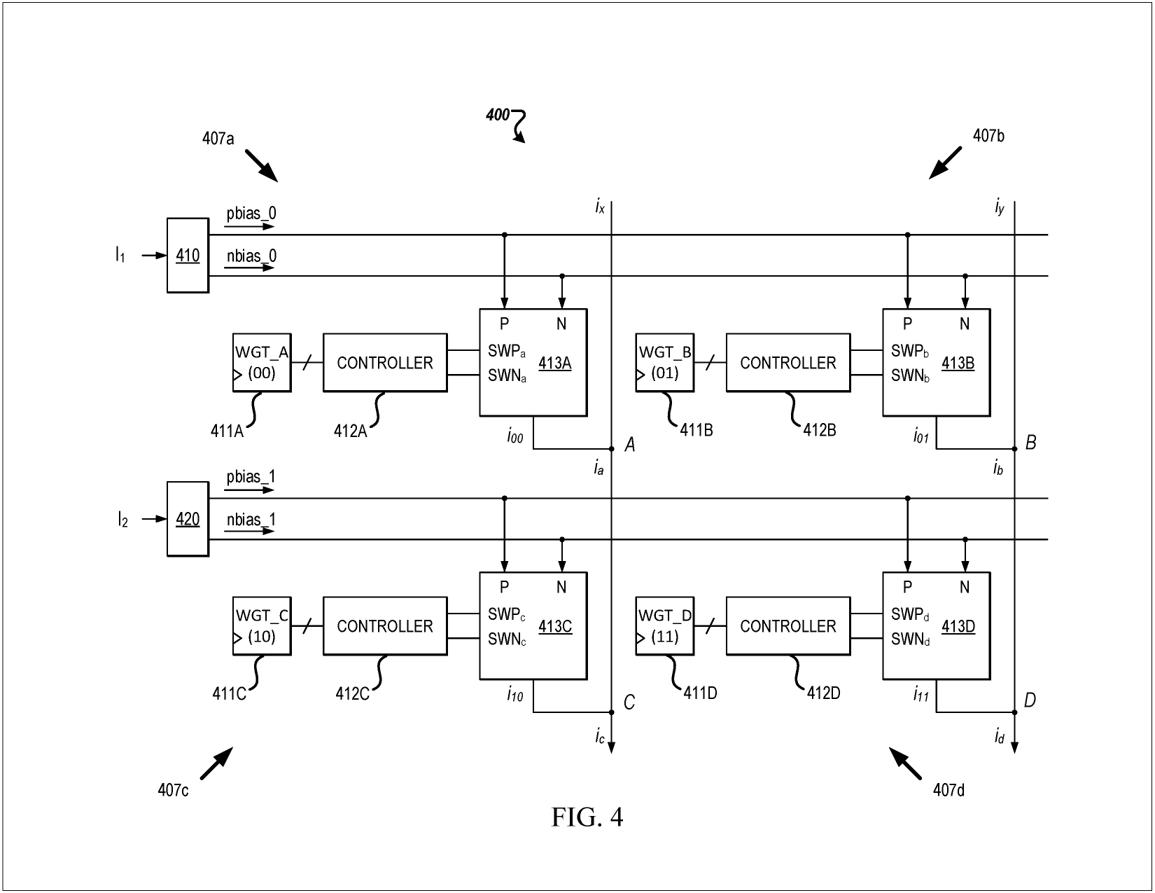

In the multiplications performed by computation nodes 307a-307d, the logic values of digital weight signals WGT_A to WGT_D are used as operands without being converted to analog signals first. More details about the multiplications are provided below with reference to FIGS. 4-6.

After performing a multiplication, computation node 307a generates current i 00, whose amplitude represents the product of a) and b) described above. Current i 00flows to connecting node A and is superposed on current i x output by an upstream computation node in computation matrix 306. In the context of computation matrix 306 where analog output signals 320 are output to ADCs 321 at the bottom of the matrix, an upstream computation node is a computation node that is disposed farther away from the bottom of computation matrix 306, while a downstream computation node is a computation node that is disposed closer to the bottom of computation matrix 306. For example, computation node 307a is an upstream computation node of computation node 307c, and computation node 307b is an upstream computation node of computation node 307d.

The superposition of currents i 00and i x can be equivalent to the accumulation of two analog signals, which results in current i a as the output of computation node 307a. In other words, after performing a multiplication operation using data provided by the AI application, computation node 307a performs an accumulation operation using the product i 00of the multiplication and an output i x of its upstream node. Similar to the superposition of currents i 00and i x at connecting node A, currents i 10and i aare superposed at connecting node A to become output current i c of computation node 307c. Likewise, currents i 01and i yare superposed at connecting node B to become output current i b of computation node 307b, and currents i 11and i bare superposed at connecting node D to become output current i d of computation node 307d. Connecting nodes A-D can be implemented as wire nodes where, according to Kirchhoff’s current law, the sum of current inflow equals the sum of current outflow.

FIG. 4 illustrates a block diagram 400 of a plurality of computation nodes 407a-407d, according to some implementations. Computation nodes 407a-407d can be similar to computation nodes 307a-307d in electronic circuit 300 of FIG. 3B. For simplicity, the below description assumes that computation nodes 407a-407d are the same as computation nodes 307a-307d, respectively, which constitute a 2-by-2 subset of computation matrix 306 of FIG. 3A.

Using computation node 407a as an example, computation node 407a is configured to perform multiplication using current I₁ as a multiplicand and using digital weight signal WGT_A (which equals 2’b00 in this example) as a multiplier, as described above with reference to FIG. 3B. The multiplication generates currents i00 . Computation node 407a is configured to then perform accumulation by superposing currents i00 and ix to output result current ia at connecting node A.

To perform the multiplication, computation node 407a has bias circuit 410, controller 412A, and multiplication circuit 413A. Controller 412A and multiplication circuit 413A can be collectively referred to as a computation circuit. Controller 412A can be similar to at least a portion of controller 220 illustrated in FIG. 2.

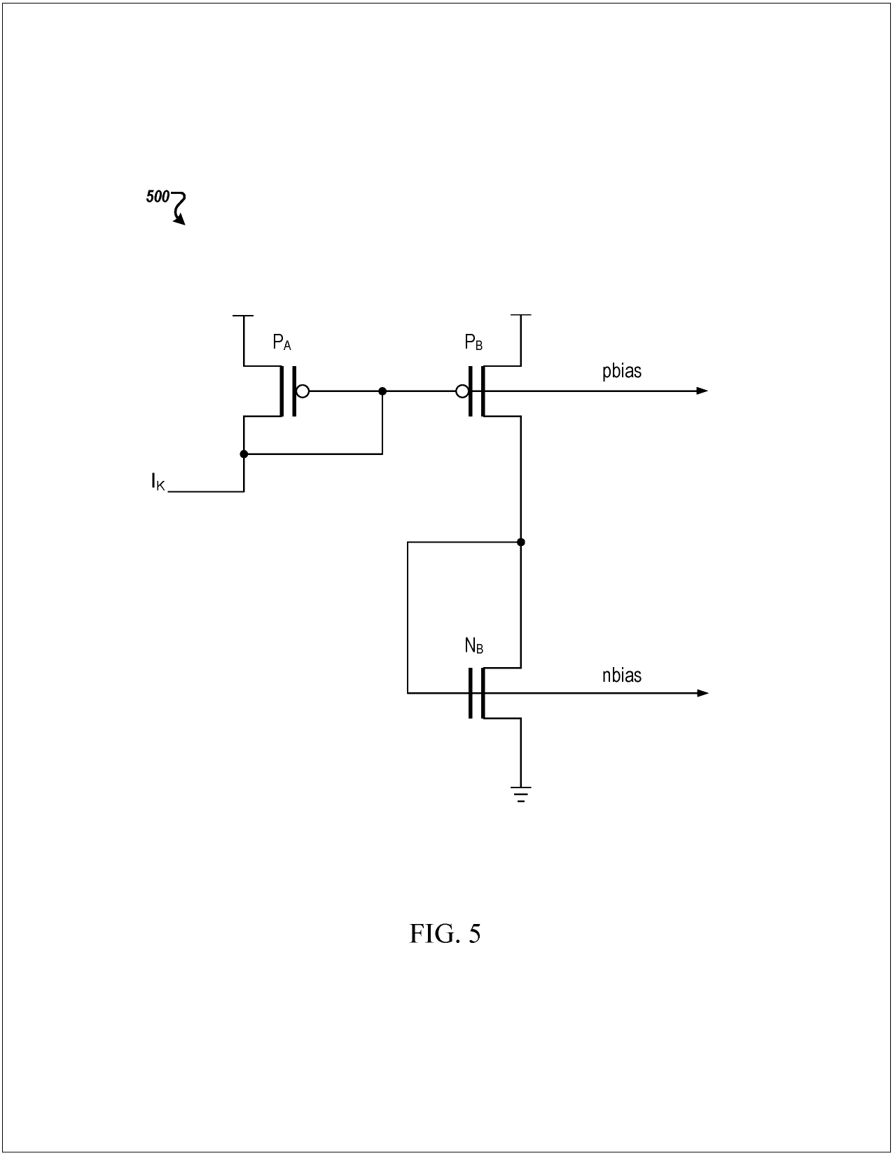

Bias circuit 410 receives current I₁ of an analog input signal (e.g., analog input signal 305m of FIG. 3B) and generates positive bias current (e.g., a bias current with a positive amplitude) pbias_0 and negative bias current (e.g., a bias current with a negative amplitude) nbias_0, which both flow to multiplication circuit 413A. Here, the positiveness or negativeness of a current amplitude can be determined as relative to an arbitrarily defined flow direction. For example, if the flow direction is defined as from bias circuit 410 to multiplication circuit 413A, then a current having positive charges moving from bias circuit 410 to multiplication circuit 413A has a positive amplitude, whereas a current having positive charges moving from multiplication circuit 413A to bias circuit 410 has a negative amplitude. In some implementations, magnitudes of bias currents pbias_0 and nbias_0 have the same absolute value but are opposite to each other. To generate bias currents pbias_0 and nbias_0, bias circuit 410 can use a current mirror circuit, which is described later with reference to FIG. 5.

Multiplication circuit 413A is configured to receive bias currents pbias_0 and nbias_0 at inputs P and N, respectively. Multiplication circuit 413A is also configured to receive, from controller 412A, positive switch signal SWPₐ and negative switch signal SWNₐ, which are digital signals that control one or more switches of multiplication circuit 413A to perform the multiplication operation and output currents i00.

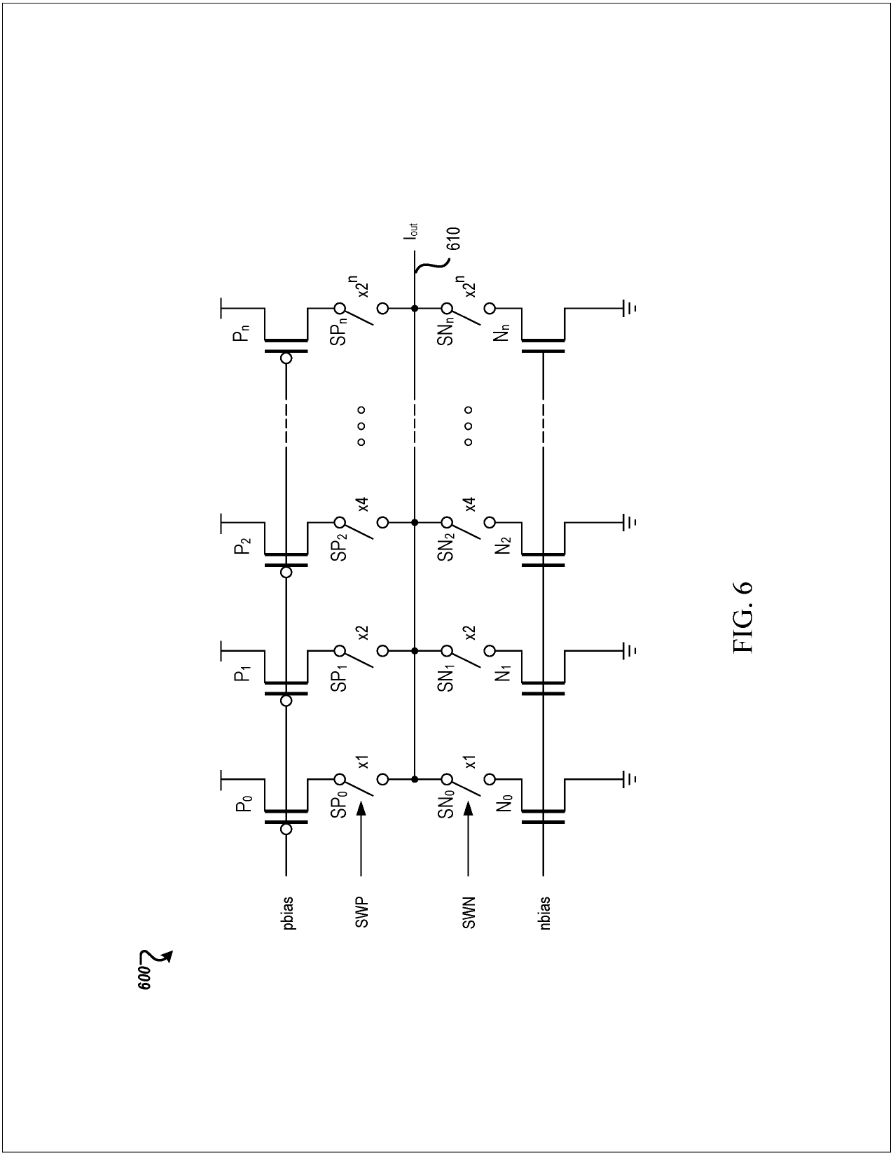

Controller 412A is configured to receive digital weight signal WGT_A from register circuit 411A, which can be synchronized with controller 412A to output a digital code (e.g., 2’b00 in the example of FIG. 4) each computation cycle. Controller 412A outputs switch signals SWPₐ and SWNₐ according to the digital code to control multiplication circuit 413A to perform multiplication. The mechanism of performing the multiplication operation is described later with reference to FIG. 6.

Computation nodes 407b-407d are configured to operate similarly to computation node 407a. For example, computation node 407b includes multiplication circuit 413B configured to receive bias currents pbias_0 and nbias_0 from bias circuit 410. Likewise, computation nodes 407c and 407d include multiplication circuits 413C and 413D, respectively, which are configured to receive bias currents pbias_1 and nbias_1 from bias circuit 420. In a more general scenario, multiple computation nodes in the same row of a computation matrix can receive bias currents from the same bias circuit. Alternatively or additionally, at least two computation nodes in the same row of a computation matrix can receive bias currents from multiple bias circuits, even though the amplitudes of bias currents are the same across the multiple bias circuits.

Similar to the configuration of multiplication circuit 413A, multiplication circuit 413B is configured to receive positive switch signal SWP_{b} and negative switch signal SWN_{b} from controller 412B, which is configured to receive digital weight signal WGT_B from register circuit 411B. Multiplication circuit 413C is configured to receive positive switch signal SWP_{c} and negative switch signal SWN_{c} from controller 412C, which is configured to receive digital weight signal WGT_C from register circuit 411C. Multiplication circuit 413D is configured to receive positive switch signal SWP_{d} and negative switch signal SWN_{d} from controller 412D, which is configured to receive digital weight signal WGT_D from register circuit 411D.

Similar to the superposition of i00 and iₓ at connecting node A, current i01 output by multiplication circuit 413B is superposed with current iy to become result current ib . Likewise, current i10 output by multiplication circuit 413C is superposed with current ia to become result current ic, and current i11 output by multiplication circuit 413D is superposed with current ib to become result current id.

FIG. 5 illustrates an example current mirror circuit 500, according to some implementations. Current mirror circuit 500 can be instantiated as, e.g., bias circuits 410 or 420 in the electronic circuit illustrated in FIG. 4. When instantiated as bias circuits 410 or 420, input current I_{K} to current mirror circuit 500 can be the same as currents I₁ or I₂, respectively.

Current mirror circuit 500 includes transistors P_{A}, P_{B}, and N_{B}, which can be metal-oxide-semiconductor field-effect transistors (MOSFETs). As illustrated, transistors P_{A} and P_{B} are PMOS transistors, whereas transistor N_{B} is an NMOS transistor. Transistors P_{A} and N_{B} are diode-connected, e.g., with their respective gate terminals coupled to their respective drain terminals. The gate terminal of transistor P_{A} is coupled to the gate terminal of transistor P_{B}, and the drain terminal of transistor P_{B} is coupled to the drain and gate terminals of transistor N_{B}.

Current mirror circuit 500 receives input current I_{K} as a reference current at the drain terminal of transistor P_{A}. Current mirror circuit 500 also provides positive bias current pbias at the gate terminal of transistor P_{B} (which is coupled to the gate terminal of transistor P_{A}) and provides negative bias current nbias at the gate terminal of transistor N_{B} (which is coupled to the drain terminal of transistor P_{B}). When transistors P_{A}, P_{B}, and N_{B} are fabricated to have the same dimensions, positive bias current pbias can mirror the amplitude and direction of input current I_{K}, and negative bias current nbias can mirror the amplitude input current I_{K} but flow in an opposite direction. By changing the dimension of transistors P_{A}, P_{B}, and N_{B}, it is possible to scale (e.g., increase or decrease) the amplitudes of bias currents pbias and nbias. Furthermore, because transistor P_{A} is diode-connected, transistor P_{A} can block a sink current that flows in a direction opposite to that of input current I_{K}, thereby operating as a rectified linear unit (ReLU).

FIG. 6 illustrates an example multiplication circuit 600, according to some implementations. Multiplication circuit 600 can be instantiated as, e.g., any of multiplication circuits 413A-413D in the electronic circuit illustrated in FIG. 4. For example, multiplication circuit 600 can be instantiated as multiplication circuit 413A. In such implementations, bias currents pbias_0 and nbias_0, which are input to multiplication circuit 413A, correspond to bias currents pbias and nbias, respectively, which are input to multiplication circuit 600. Also in such implementations, switch signals SWPₐ and SWNₐ, which are input to multiplication circuit 413A, correspond to switch signals SWP and SWN, respectively, which are input to multiplication circuit 600.

Multiplication circuit 600 includes a plurality of groups of weighting transistors. A first group includes PMOS transistor P₀ and NMOS transistor N₀, whose drain terminals are respectively coupled to switches SP₀ and SN₀ and whose source terminals are respectively coupled to a high voltage supply (e.g., VDD) and a low voltage supply (e.g., ground). A second group includes PMOS transistor P₁ and NMOS transistor N₁, whose drain terminals are respectively coupled to switches SP₁ and SN₁ and whose source terminals are respectively coupled to the high voltage supply and the low voltage supply. Likewise, an (n+1)-th group (n is a positive integer) includes PMOS transistor Pₙ and NMOS transistor Nₙ, whose drain terminals are respectively coupled to switches SPₙ and SNₙ and whose source terminals are respectively coupled to the high voltage supply and the low voltage supply. Multiplication circuit 600 also includes output node 610 coupled to the nodes between switches SPᵢ and SNᵢ (i=0, 1, 2, … n). Accordingly, in each group and depending on the On/Off status of the switches in that group, the PMOS and NMOS transistors can provide paths for currents to flow through the transistors to output node 610.

The currents flowing from all paths to output node 610 together become output current Iₒᵤₜ of multiplication circuit 600. For example, when multiplication circuit 600 is instantiated as multiplication circuit 413A of FIG. 4, output current Iₒᵤₜ can be the same as output current i 00 output by multiplication circuit 413A.

The groups of PMOS and NMOS transistors each can be associated with a different multiplier. The multiplier mᵢ of the (i+1)-th group represents a ratio of the current amplitude of the (i+1)-th path divided by the amplitude of a bias current. Using the first group (i=0) as an example, when SP₀ is switched on, the current flowing through PMOS transistor P₀ to output node 610 equals positive bias current pbias multiplied by the multiplier m₀. Assuming positive bias current pbias mirrors current I₁ of FIGS. 3B and 4 with no scaling, switching on SP₀ can generate an output current at output node 610 that represents I₁×m₀. Likewise, when SN₀ is switched on, the current flowing through NMOS transistor N₀ to output node 610 equals negative bias current nbias multiplied by the multiplier m₀. Assuming negative bias current nbias mirrors the opposite of current I₁ of FIGS. 3B and 4, switching on SN₀ can generate an output current at output node 610 that represents I₁×(-m₀).

The association between a group of PMOS and NMOS transistors and the multiplier of that group can be obtained by varying the characteristics of transistors for different groups. One way of varying the characteristics for different groups is to vary the dimensions of the transistors. For example, in order for group A to have twice the multiplier of group B, the PMOS and NMOS transistors of group A can each be made approximately twice the width of those of group B, or can be made approximately half the length of those of group B.

The association between a group of PMOS and NMOS transistors and the multiplier of that group can be obtained by having different numbers of transistors for different groups. For example, in some implementations, instead of having only one PMOS transistor and one NMOS transistor in each group, some groups can have more than one PMOS transistor and more than one NMOS transistor. Accordingly, assuming all the PMOS transistors in the same group are coupled in series and all the NMOS transistors in the same group are also coupled in series, group A can have half the number of PMOS transistors and half the number of NMOS transistors of group B in order to have twice the multiplier of group B. Alternatively or additionally, assuming all the PMOS transistors in the same group are coupled in parallel and all the NMOS transistors in the same group are also coupled in parallel, group C can have twice the number of PMOS transistors and twice the number of NMOS transistors of group D in order to have twice the multiplier of group B.

In addition to varying the dimensions of transistors and varying the number of transistors, there are other ways of associating a group of transistors with a multiplier. For example, some implementations can have groups of transistors that differ both in dimension and in number. One of ordinary skill in the art reading this disclosure would have readily understood the other approaches that are within the spirit of this disclosure and yet omitted from description.

In some implementations, the multipliers can be, e.g., powers of two. For example, PMOS transistor P₀ and NMOS transistor N₀ in the first group can correspond to a multiplier of m₀=2⁰=1, PMOS transistor P₁ and NMOS transistor N₁ in the second group can correspond to a multiplier of m₁=2¹=2, PMOS transistor P₂ and NMOS transistor N₂ in the third group can correspond to a multiplier of m₂=2²=4, PMOS transistor Pₙ and NMOS transistor Nₙ in the (n+1)-th group can correspond to a multiplier of m₂=2ⁿ. Some other implementations can have different multipliers for the groups of PMOS and NMOS transistors.

Multiplication circuit 600 performs multiplications by switching switches SPᵢ and SNᵢ in each group according to switch signals SWP and SWN. Each of switch signals SWP and SWN can have (n+1) bits, with each bit controlling a corresponding switch. For example, SWP[0] and SWN[0] can respectively control switches SP₀ and SN₀, SWP[1] and SWN[1] can respectively control switches SP₁ and SN₁, and SWP[n] and SWN[n] can respectively control switches SPₙ and SNₙ.

Switch signals SWP and SWN are generated by a controller based on the value represented by the digital weight signals, such as digital weight signals WGT_A to WGT_D in implementations illustrated in FIGS. 3B and 4. In the example of computation node 407a of FIG. 4 where digital weight signal WGT_A equals 2’b00, controller 412A can decode WGT_A and determine that 2’b00 represents a decimal value of 0. With this determination, controller 412A can output switch signals SWPₐ and SWNₐ to switch off all switches SPᵢ and SNᵢ of multiplication circuit 413A. This can make Iₒᵤₜ at output node 610 of multiplication circuit 413A equal 0.

Similarly, in the example of computation node 407b of FIG. 4 where digital weight signal WGT_B equals 2’b01, controller 412B can decode WGT_B and determine that 2’b01 represents a decimal value of 1. With this determination, controller 412B can output switch signals SWP_{b} and SWN_{b} to switch on only switch SP₀ of multiplication circuit 413B. This can make Iₒᵤₜ at output node 610 of multiplication circuit 413B equal 1×(the amplitude of pbias).

Similarly, in the example of computation node 407c of FIG. 4 where digital weight signal WGT_C equals 2’b10, controller 412C can decode WGT_C and determine the value represented by 2’b10. In implementations where the coding scheme of 2’b10 is natural binary, controller 412C can determine that 2’b10 represents a decimal value of 2. With this determination, controller 412C can output switch signals SWP_{c} and SWN_{c} to switch on only switch SP₁ of multiplication circuit 413C. This can make Iₒᵤₜ at output node 610 of multiplication circuit 413C equal 2×(the amplitude of pbias). Alternatively, in implementations where the coding scheme of 2’b10 is grey code, controller 412C can determine that 2’b10 represents a decimal value of 3. With this determination, controller 412C can output switch signals SWP_{c} and SWN_{c} to switch on both switches SP₀ and SP₁ of multiplication circuit 413C. This can make Iₒᵤₜ at output node 610 of multiplication circuit 413C equal (1+2)×(the amplitude of pbias) = 3×(the amplitude of pbias).

In addition to natural binary code and grey code illustrated above, the digital weight signals provided to a multiplication circuit can possibly be coded based on other coding schemes, such as 2’s supplement, cyclic code, hamming code, or other error correction coding schemes. Depending on the coding scheme, the controller in the multiplication circuit can determine the value behind the coded digital weight signal and output switch signals SWP and SWN accordingly. When the controller determines that the decimal value behind a digital weight signal is negative, the controller can use switch signals SWP and SWN to switch on one or more switches SNᵢ to have negative currents flow to output node 610, thereby realizing a subtraction operation when output current Iₒᵤₜ is then superposed at a connecting node. In some implementations, the controller can be configured to switch off all switches SPᵢ and only control switches SNᵢ. These implementations can be used to realize the functions of a ReLU, a Gaussian error linear unit (GeLU), or a sigmoid linear unit (SiLU), which are commonly used in neural networks.

As described above with reference to FIGS. 3A-6, the MAC architecture in implementations of this disclosure use analog values of currents to represent data, which allows computations to be conveniently performed as currents flow and merge. Compared to existing MAC techniques that use logic gates to perform computations, implementations of this disclosure reduces the circuit size and complexity and reduces the power consumption associated with computations.

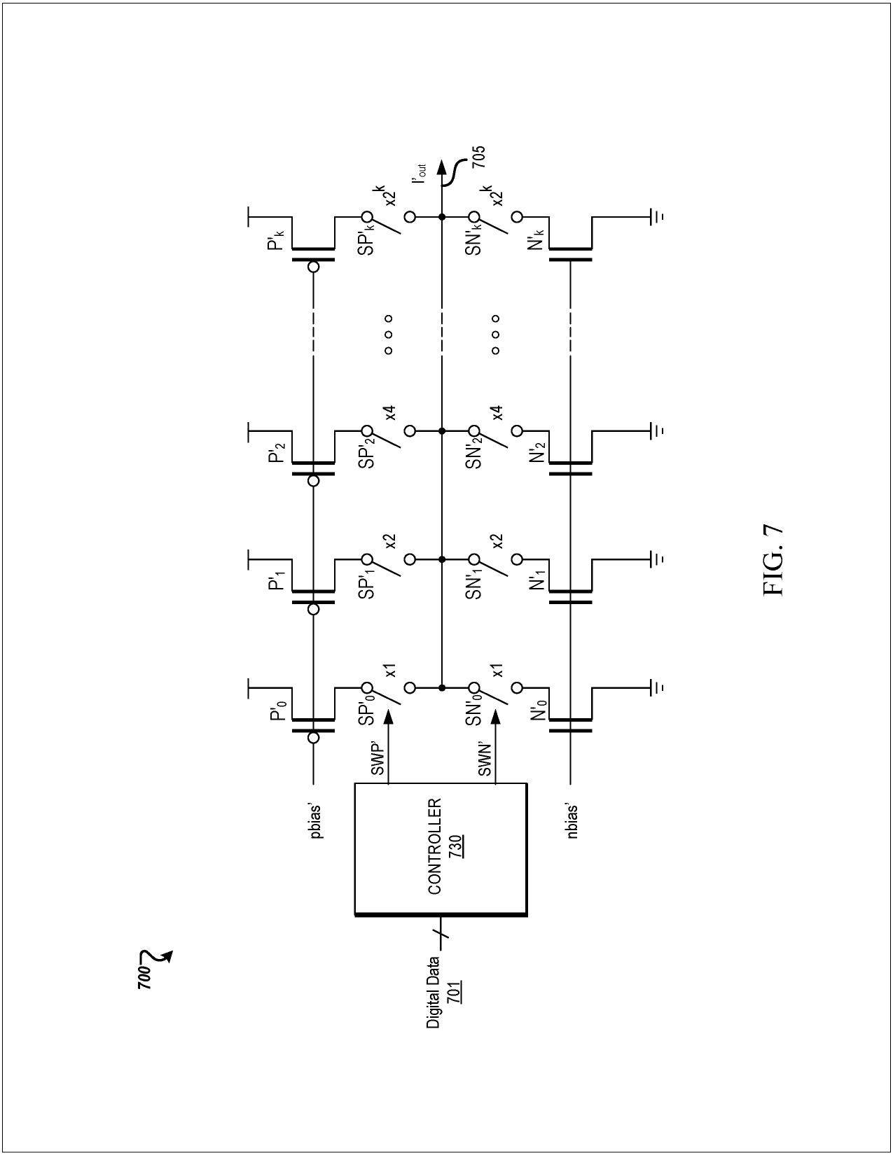

In some implementations, the architecture of multiplication circuit 600 can be similarly used to implement DAC circuits of AI accelerators, such as DACs 304 of electronic circuit 300. Example implementations are described below with reference to FIG. 7.

FIG. 7 illustrates an example DAC circuit 700, according to some implementations. Similar to multiplication circuit 600, DAC circuit 700 has (k+1) (k is a positive integer) groups of transistors P’ⱼ and N’ⱼ, (j=0, 1, 2, … k) respectively coupled to switches SP’ⱼ and SN’ⱼ. The gate terminals of transistors P’ⱼ and N’ⱼ are respectively biased by bias currents pbias’ and nbias’, which can have opposite amplitudes. Each group corresponds to a multiplier, which can be similar to multipliers mᵢ of multiplication circuit 600, e.g., powers of 2. Switches SP’ⱼ and SN’ⱼ are respectively controlled by switch signals SWP’ and SWN’, which are output by controller 730 based on digital input data 701.

DAC circuit 700 can be configured to convert digital input data 701 to current I’ₒᵤₜ, which is output at output node 705. The conversion can be achieved by setting bias currents pbias’ and nbias’ at constant levels (e.g., +1 unit and -1 unit, respectively) and controlling switches SP’ⱼ and SN’ⱼ to turn on or off based on digital input data 701. For example, when digital input data 701 is 4’b0010, controller 730 can determine (e.g., based on a truth table stored therein) that the corresponding analog current should have a magnitude of +2 units. Accordingly, controller 730 can generate switch signals SWP’ and SWN’ to turn on only switch SP’₁ such that current I’ₒᵤₜ equals 2×(the amplitude of pbias’)= 2 units. Likewise, when digital input data 701 is 4’b0111, controller 730 can determine that the corresponding analog current should have a magnitude of +7 units. Accordingly, controller 730 can generate switch signals SWP’ and SWN’ to turn on only switches SP’₀, SP’₁, and SP’₂ such that current I’ₒᵤₜ equals (1+2+4)×(the amplitude of pbias’)= 7 units.

Using DAC circuit 700 or similar DAC circuits in the MAC architecture of the above-described implementations can have many advantages. In addition to reduced circuit complexity and power consumption, the similarities between the DAC circuit architecture and the multiplication circuit architecture can increase the reusability and portability of circuit designs. For example, after expending efforts to design the multiplication circuit under various constraints (e.g., power supply, timing, temperature, or size), a circuit designer can conveniently transfer and reuse a large portion of the designed multiplication circuit when designing the DAC circuits, thereby reducing design cost. The increased reusability and portability can also streamline the fabrication process during the manufacture of an AI accelerator chip, thereby reducing manufacturing cost.

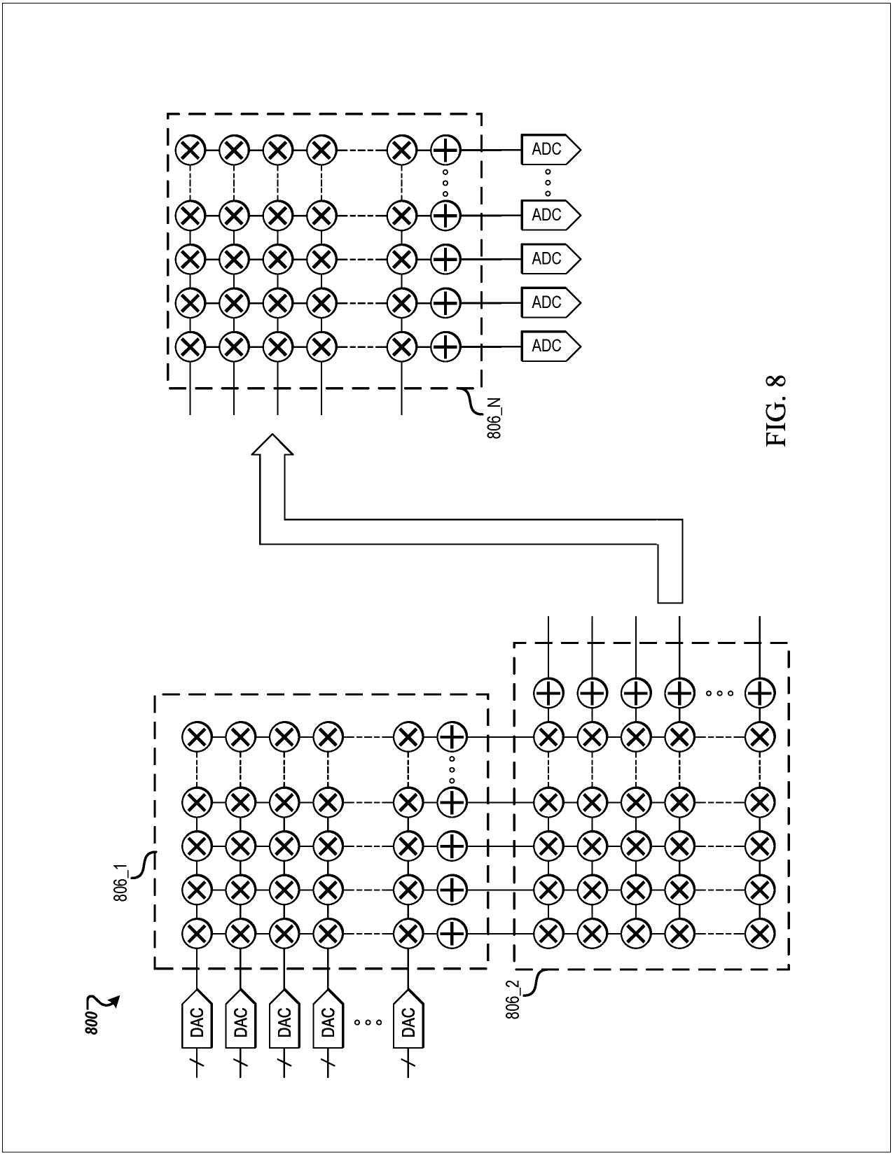

Electronic circuits according to one or more implementations described above can be conveniently expanded to increase the computation capacity. Example implementations are described below with reference to FIG. 8.

FIG. 8 illustrates an example electronic circuit 800 with a plurality of computation matrices, according to some implementations. Compared to electronic circuit 300 that is illustrated to have one computation matrix 306, electronic circuit 800 has N computation matrices (N is a positive integer greater than 1) 806_1, 806_2, … 806_N coupled to one another in a cascade structure. Each of computation matrices 806_1, 806_2, … 806_N can be similar to computation matrix 306. Computation matrices 806_1, 806_2, … 806_N can share bias circuits and/or controllers. Alternatively, some of computation matrices 806_1, 806_2, … 806_N can have their own bias circuits and/or controllers.

In some implementations, electronic circuit 800 has one or more coupling circuits configured to couple consecutive computation matrices in the cascade. The coupling circuits can include, e.g., one or more diodes that allow currents to flow unidirectionally from one computation matrix to another, thereby implementing ReLU functionality.

Using computation matrix 806_1 as an example, computation matrix 806_1 is similar to computation matrix 306 in receiving a plurality of analog input signals respectively from a plurality of DACs. Different from computation matrix 306, the analog input signals generated by computation matrix 806_1 are provided to the next matrix, computation matrix 806_2, as analog input signals. Likewise, the analog output signals of each next computation matrix are provided to the following computation matrix in the cascade, until the last computation matrix 802_N, whose analog output signals are provided to the ADCs.

The cascade structure described above with reference to FIG. 8 can be further varied according to computation needs. For example, in some implementations, the analog output signals of computation matrix 806_1 can be partitioned into multiple subsets, with each subset of analog output signals separately provided to a computation matrix with fewer columns than computation matrix 806_1. Alternatively or additionally, in some implementations, the analog output signals of computation matrix 806_1 can be provided to another computation matrix in parallel to computation matrix 806_2. Alternatively or additionally, in some implementations, the analog output signals of multiple computation matrices can be combined and collectively provided to a computation matrix with more columns than each individual computation matrix that supplies the analog input signals. One of ordinary skill in the art reading this disclosure would have readily understood the other variations that are within the spirit of this disclosure and yet omitted from description.

In the cascade structures described above, the plurality of computation matrices can correspond to a plurality of layers in multi-layer neural networks, such as a multi-layer deep neural network (DNN). When implemented according to the described cascade structures, multi-layer neural networks can perform complex computations with reduced latency and reduced power consumption because there is no memory or other storage circuitry needed between consecutive layers.

With the cascade structures described above, an AI accelerator according to some implementations can have great flexibility of addressing computation tasks with different data formats, computation complexities, data speeds, and/or circuit sizes. Moreover, because the computation matrices in the cascade can have the same or similar circuitry, the reusability and portability of circuit designs can be improved, which in turn can lead to reduced circuit size, complexity, and design and manufacturing costs.

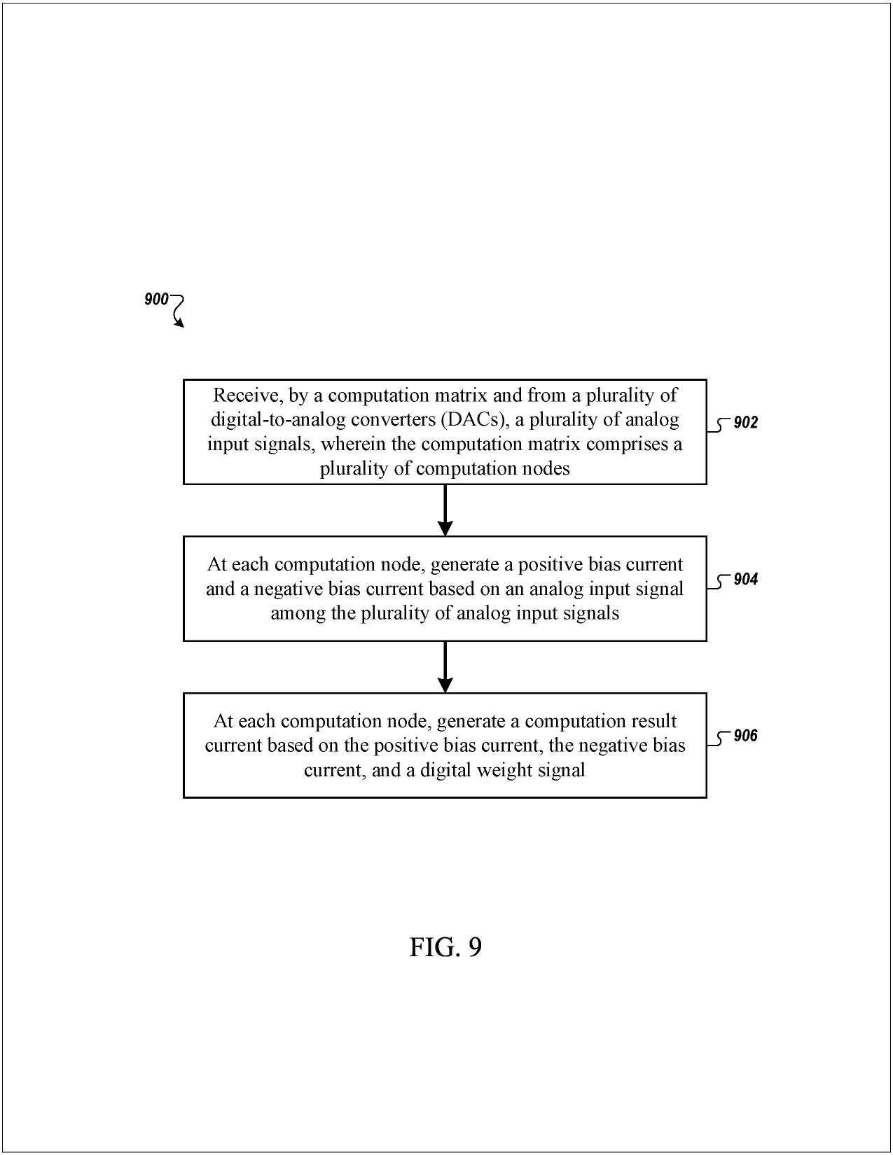

FIG. 9 illustrates a flowchart of an example method 900, according to some implementations. It will be understood that method 900 can be performed, for example, during a design phase using simulation software, during a testing phase in a laboratory environment, during a fabrication phase in a factory, or in deployment to support data processing applications.

At 902, method 900 involves receiving, by a computation matrix and from a plurality of DACs, a plurality of analog input signals. The computation matrix includes a plurality of computation nodes, such as computation node 307 of computation matrix 306 illustrated in FIG. 3A.

At 904, method 900 involves, at each computation node, generating a positive bias current and a negative bias current based on an analog input signal among the plurality of analog input signals. The generation of the positive bias current and the negative bias current can utilize a current mirror circuit, such as current mirror circuit 500 illustrated in FIG. 5.

At 906, method 900 involves, at each computation node, generating a computation result current based on the positive bias current, the negative bias current, and a digital weight signal. The generation of the computation result current can utilize a computation circuit, such as those illustrated in FIGS. 3B and 4.

While this specification includes many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

What is claimed is:

1. An electronic circuit comprising:
a plurality of digital-to-analog converters (DACs) configured to generate a plurality of analog input signals; and
a computation matrix coupled to the plurality of DACs and configured to receive the plurality of analog input signals from the plurality of DACs, wherein the computation matrix comprises a plurality of computation nodes,
wherein each computation node comprises
a bias circuit configured to generate a positive bias current and a negative bias current based on an analog input signal among the plurality of analog input signals, and
a computation circuit configured to generate a computation result current based on the positive bias current, the negative bias current, and a digital weight signal.

2. The electronic circuit of claim 1, wherein, for each computation node, the bias circuit comprises a current mirror circuit.

3. The electronic circuit of claim 2, wherein, for each computation node, the current mirror circuit comprises:
an input transistor configured to receive analog input signal;
a p-type metal–oxide–semiconductor (PMOS) output transistor configured to generate the positive bias current; and
an n-type metal–oxide–semiconductor (NMOS) output transistor configured to generate the negative bias current.

4. The electronic circuit of claim 1,
wherein, for each computation node, the computation circuit comprises a plurality of groups of weighting transistors, an output node, and a control circuit,
wherein each group of weighting transistors comprises
at least one a p-type metal–oxide–semiconductor (PMOS) transistor,
at least one n-type metal–oxide–semiconductor (NMOS) output transistor,
a first switch configured to couple the at least one PMOS transistor to the output node, and
a second switch configured to couple the at least one NMOS transistor to the output node, and
wherein the control circuit is configured to control the first switch and the second switch based on the digital weight signal.

5. The electronic circuit of claim 4, wherein, for each computation node, the computation result current of that computation node is a superposition of i) a current at the output node of that computation node, and ii) a computation result current generated by an adjacent computation node in the computation matrix.

6. The electronic circuit of claim 4, wherein, for each computation node, the plurality of groups of weighting transistors correspond to a plurality of multipliers.

7. The electronic circuit of claim 6, wherein each group of weighting transistors has at least one of:
a number of PMOS transistors corresponding to a multiplier of that group and a number of NMOS transistors corresponding to the multiplier of that group,
a width of the PMOS transistors corresponding to the multiplier of that group and a width of the NMOS transistors corresponding to the multiplier of that group, or
a length of the PMOS transistors corresponding to the multiplier of that group and a length of the NMOS transistors corresponding to the multiplier of that group.

8. The electronic circuit of claim 6, wherein, for each computation node, the plurality of multipliers are powers of 2.

9. The electronic circuit of claim 1,
wherein the computation matrix comprises a plurality of rows and a plurality of columns, and
wherein the plurality of DACs are respectively coupled to the plurality of rows.

10. The electronic circuit of claim 9, further comprising a plurality of analog-to-digital converters (ADCs) coupled to the plurality of columns and configured to receive a plurality of analog output signals from the computation matrix and convert the plurality of analog output signals to a plurality of digital output signals.

11. The electronic circuit of claim 1,
wherein each DAC comprises a plurality of groups of converting transistors, an output node, and a control circuit configured to receive an input digital signal,
wherein each group of converting transistors comprises
at least one a p-type metal–oxide–semiconductor (PMOS) transistor,
at least one n-type metal–oxide–semiconductor (NMOS) output transistor,
a first switch configured to couple the at least one PMOS transistor to the output node, and
a second switch configured to couple the at least one NMOS transistor to the output node, and
wherein the control circuit is configured to control the first switch and the second switch based on the input digital signal.

12. The electronic circuit of claim 1, wherein the computation matrix is a first computation matrix, and wherein the electronic circuit further comprises:
one or more second computation matrices; and
a coupling circuit connected between the first computation matrix and the one or more second computation matrices.

13. The electronic circuit of claim 12, wherein the coupling circuit comprises a plurality of diodes.

14. The electronic circuit of claim 1, further comprising:
at least one demultiplexer configured to receive digital input data; and
a plurality of first-in-first-out (FIFO) circuits coupled between the at least one demultiplexer and the plurality of DACs.

15. The electronic circuit of claim 10, further comprising:
at least one multiplexer configured to generate digital output data; and
a plurality of first-in-first-out (FIFO) circuits coupled between the at least one multiplexer and the plurality of ADCs.

16. An electronic device comprising:
a receiver port configured to receive digital input data;
a transmitter port configured to transmit digital output data; and
a computation circuit configured to receive the digital input data from the receiver port and provide the digital output data to the transmitter port,
wherein the computation circuit comprises:
a plurality of digital-to-analog converters (DACs) configured to generate a plurality of analog input signals based on the digital input data;
a computation matrix coupled to the plurality of DACs and configured to receive the plurality of analog input signals from the plurality of DACs and generate a plurality of analog output signals, wherein the computation matrix comprises a plurality of computation nodes; and
a plurality of analog-to-digital converters (ADCs) coupled to the computation matrix and configured to receive the plurality of analog output signals from the computation matrix and convert the plurality of analog output signals to a plurality of digital output signals;
wherein each computation node comprises
a bias circuit configured to generate a positive bias current and a negative bias current based on an analog input signal among the plurality of analog input signals, and
a computation circuit configured to generate a computation result current based on the positive bias current, the negative bias current, and a digital weight signal.

17. The electronic device of claim 16,
wherein, for each computation node, the computation circuit comprises a plurality of groups of weighting transistors, an output node, and a control circuit,
wherein each group of weighting transistors comprises
at least one a p-type metal–oxide–semiconductor (PMOS) transistor,
at least one n-type metal–oxide–semiconductor (NMOS) output transistor,
a first switch configured to couple the at least one PMOS transistor to the output node, and
a second switch configured to couple the at least one NMOS transistor to the output node, and
wherein the control circuit is configured to control the first switch and the second switch based on the digital weight signal.

18. The electronic device of claim 17, wherein, for each computation node, the computation result current of that computation node is a superposition of i) a current at the output node of that computation node, and ii) a computation result current generated by an adjacent computation node in the computation matrix.

19. The electronic device of claim 17, wherein, for each computation node, the plurality of groups of weighting transistors correspond to a plurality of multipliers.

20. A method comprising:
receiving, by a computation matrix and from a plurality of digital-to-analog converters (DACs), a plurality of analog input signals, wherein the computation matrix comprises a plurality of computation nodes;
at each computation node,
generating a positive bias current and a negative bias current based on an analog input signal among the plurality of analog input signals; and
generating a computation result current based on the positive bias current, the negative bias current, and a digital weight signal.
